(19) United States
(12) Patent Application Publication
(10) Pub. No.: US 2009/0087943 A1
(43) Pub. Date: Apr. 2, 2009

(54) METHOD FOR FORMING LARGE GRAIN POLYSILICON THIN FILM MATERIAL

(76) Inventor: JIAN ZHONG YUAN, Simi Valley, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 12/240,923

(22) Filed: Sep. 29, 2008

Related U.S. Application Data
(60) Provisional application No. 60/976,393, filed on Sep. 28, 2007.

(51) Int. Cl. H01L 21/00

(52) U.S. Cl. 438/97; 257/E21.001

(57) ABSTRACT

A method of forming polysilicon thin film material for photovoltaic devices. The method includes providing a polycrystalline silicon substrate. The polycrystalline silicon substrate includes a surface region, a backside region, and a thickness. In a specific embodiment, the method forms a polysilicon thin film material using a deposition process overlying the surface region of the polycrystalline silicon substrate. The polysilicon thin film material is characterized by a grain size greater than about 0.1 mm.

### CROSS-REFERENCES TO RELATED APPLICATIONS

This application claims priority to provisional patent application Ser. No. 60/976,393; filed on Sep. 28, 2007; commonly assigned, and of which is hereby incorporated by reference for all purposes.

### STATEMENT AS TO RIGHTS TO INVENTIONS MADE UNDER FEDERALLY SPONSORED RESEARCH AND DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK

NOT APPLICABLE

### BACKGROUND OF THE INVENTION

The present invention is directed to photovoltaic material. More particularly, the present invention provides a method and structure for manufacture of polysilicon thin film material for photovoltaic applications. Merely by way of example, the present method and structure have been implemented using a polysilicon thin film material having large grain size, but it would be recognized that the invention may be implemented using other materials.

As the population of the world increases, industrial expansion has lead to an equally large consumption of energy. Energy often comes from fossil fuels, including coal and oil, hydroelectric plants, nuclear sources, and others. Almost every element of our daily lives depends, in part, on oil, which is becoming increasingly scarce. Accordingly, other and alternative sources of energy have been developed.

Concurrent with oil, we have also relied upon other very useful sources of energy such as hydroelectric, nuclear, and the like to provide our electricity needs. As an example, most of our conventional electricity requirements for home and business use comes from turbines run on coal or other forms of fossil fuel, nuclear power generation plants, and hydroelectric plants, as well as other forms of renewable energy. Most importantly, much if not all of the useful energy found on the Earth comes from our sun. Generally all common plant life on the Earth achieves life using photosynthesis processes from sun light. Fossil fuels such as oil were also developed from biological materials derived from energy associated with the sun. For human beings, sunlight has been essential. For life on the planet Earth, the sun has been our most important energy source and fuel for modern day solar energy.

Solar energy possesses many characteristics that are very desirable. Solar energy is renewable, clean, abundant, and often widespread. Certain technologies developed often capture solar energy, store it, and convert it into other useful forms of energy, for example, electrical and/or thermal energy.

Solar devices have been developed to convert sunlight into energy. As merely an example, solar thermal panels often convert electromagnetic radiation from the sun into thermal energy for heating homes, running certain industrial processes, or driving high grade turbines to generate electricity. As another example, solar photovoltaic panels convert sunlight directly into electricity for a variety of applications. Accordingly, solar panels have great benefit to human users. They can diversify our energy requirements and reduce the world's dependence on oil and other potentially detrimental sources of energy.

Although solar devices have been used successful for certain applications, there are still certain limitations. Solar cells are often costly. Solar cells are often composed of silicon bearing wafer materials. Such silicon bearing wafer materials are often costly and difficult to manufacture efficiently on a large scale. That is, silicon bearing wafer materials are often difficult to find and purchase from limited sources of photovoltaic silicon bearing materials. These and other limitations are described throughout the present specification, and may be described in more detail below.

From the above, it is seen that techniques for providing photovoltaic silicon bearing materials is highly desirable.

### BRIEF SUMMARY OF THE INVENTION

According to embodiments of the present invention, a method for forming a polysilicon thin film material is provided. More particularly, embodiments according to the present invention provide a method and a structure for a large grain polysilicon thin film material. Merely by way of example, embodiments according to the present invention can be applied to fabrication of photovoltaic devices. But it would be recognized that the present invention has a broader range of applicability.

In a specific embodiment, a method of forming a polysilicon thin film material is provided. The method includes providing a polycrystalline silicon substrate member. The polycrystalline silicon substrate member includes a surface region, a thickness, and a backside region. The method includes depositing a polysilicon thin film material overlying the surface region of the polycrystalline silicon substrate member. In a specific embodiment, the polysilicon thin film material is characterized by a grain size greater than about 0.1 mm.

In an alternative embodiment, an alternative method of forming a polysilicon thin film material is provided. The alternative method includes providing a silicon substrate member. The silicon substrate member includes a surface region, a thickness, and a backside region. The alternative method includes depositing a polysilicon thin film material overlying the surface region of the silicon substrate member. In a specific embodiment, the polysilicon thin film material is characterized by a grain size greater than about 0.1 mm.

Many benefits are achieved by way of present invention over conventional techniques. For example, the present technique provides an easy to use process that relies upon convention technology. In some embodiments, the present method provides a polysilicon thin film material that can be a low cost alternative to the conventional polysilicon material used in photovoltaic device application. Additionally, the method provides a process that is compatible with conventional process technology without substantial modifications to conventional equipment and processes. Depending upon the embodiment, one or more these benefits may be achieved. These and other benefits will be described in more detail throughout the present specification and more particularly below.

### BRIEF DESCRIPTION OF THE DRAWINGS

FIG. 1 is a simplified flow diagram illustrating a method of forming large grain polysilicon thin film material according to an embodiment of the present invention.

FIG. 2-5 are simplified diagram illustrating a method of forming large grain polysilicon thin film material according to an embodiment of the present invention.

### DETAILED DESCRIPTION OF THE INVENTION

According to the present invention, techniques related to photovoltaic materials are provided. More particularly, the present invention provides a method and structure for forming polysilicon thin film material for photovoltaic application. Merely by way of example, the present method and structure have been applied to large grain polysilicon thin film, but it would be recognized that the invention may have other morphologies. Further details of the embodiments of the present invention can be found throughout the present specification and more particularly below.

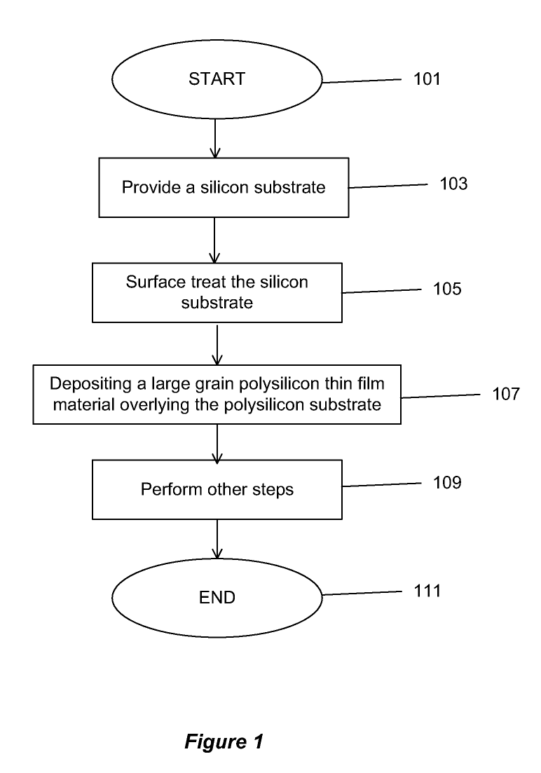

FIG. 1 is a simplified flow diagram illustrating a method of forming polysilicon thin film material having a large grain size according to an embodiment of the present invention. As shown, the method begins with a START step (Step 101). The method includes providing a silicon substrate (Step 103) including a surface region. The silicon substrate can include material such as a large grain polycrystalline silicon material in a specific embodiment. The polycrystalline silicon substrate can be wafers, large area polycrystalline silicon substrate member and others. The method includes performing a surface treatment process on the silicon substrate (Step 105). In a specific embodiment, the method deposits a polysilicon thin film material (Step 107) overlying the surface region of the silicon substrate, for example, the polycrystalline silicon substrate. Preferably, the polysilicon thin film material is characterized by a grain size greater than about 0.1 mm. The method then performs other steps including providing photovoltaic devices in the polysilicon thin film material (Step 109) and ends (Step 111). Of course there can be other variations, modifications, and alternatives.

The above sequence of steps provides a method of forming a polysilicon thin film material having a large grain size according to an embodiment of the present invention. As shown, the method uses a combination of steps including a way of forming a large grain polysilicon thin film material overlying a silicon substrate in a specific embodiment. In a preferred embodiment, the large grain polysilicon material can be formed overlying a large grain polycrystalline silicon material. Other variations and alterations can also be provided where one of more steps are added, one or more steps are removed, or one or more steps are provided in a different sequence without departing from the scope of claims therein. One skilled in the art would recognize many other variations, modifications, and alternatives.

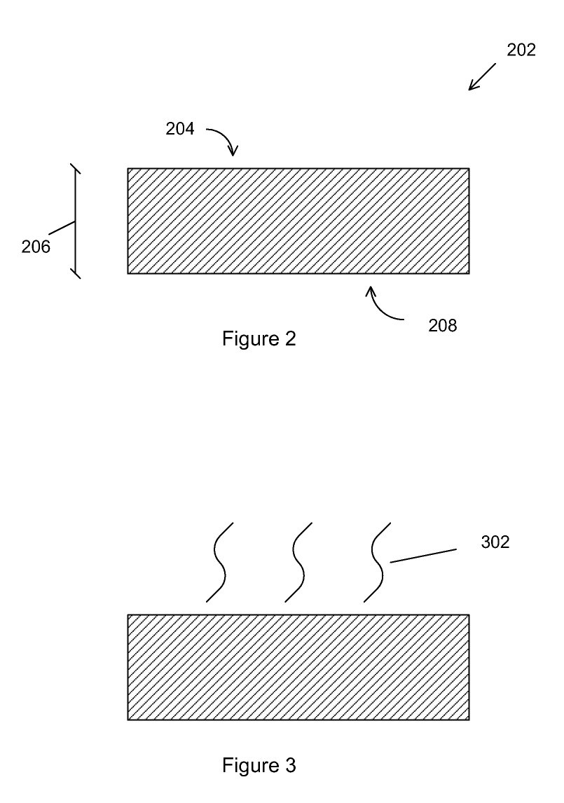

FIG. 2-5 are simplified diagrams illustrating a method of forming a polysilicon thin film material overlying a silicon substrate, for example a polycrystalline silicon substrate according to an embodiment of the present invention. These diagrams are merely example and should not unduly limit the claims herein. On skilled in the art would recognize other modifications, variations, and alternatives. As shown in FIG. 2, the method includes providing a silicon substrate member 202. The silicon substrate member includes a surface region 204, a thickness 206, and a backside region 208. In a specific embodiment, the substrate member is a polycrystalline silicon substrate characterized by a silicon purity level greater than about 0.99 or 2N and a suitable grain size. The polycrystalline silicon substrate can be a semiconductor grade polycrystalline silicon, a metallurgical grade polycrystalline silicon or others depending on the application. The silicon substrate member can also be provided in various shapes and dimensions. For example, the silicon substrate member can be provided as silicon wafers. For example, the silicon wafers can be squares having truncated corners and having a dimension of 125 mm by 125 mm, 156 mm by 156 mm, 210 mm by 210 mm, but can be others. Alternatively, the silicon wafers can be circular having diameters up to 300 mm, or others. The silicon wafer can have a thickness ranging from about 100 microns to a few millimeters depending on the embodiment. The silicon substrate member can also be provided as a large area substrate having dimension greater than about 2 meter by 2 meter. Of course there can be other variations, modifications, and alternatives.

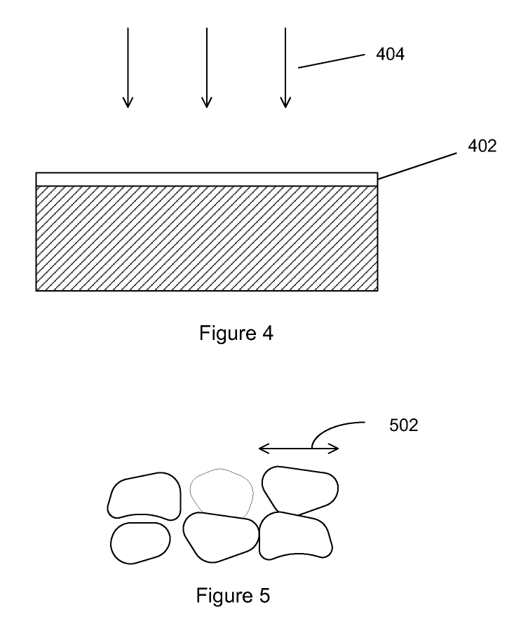

Referring to FIG. 3, the method includes performing a surface treatment process 302 on the silicon substrate member, for example the polycrystalline silicon substrate. The surface treatment process may include a suitable cleaning process followed by drying to remove contaminants and/or particulates from the surface region. Such cleaning process may include using a chemical cleaning process such as an RCA clean followed by rinsing and drying. The cleaning process may use an organic solvent, for example, an alcohol, to remove organic contaminants. The surface treatment process may include a surface cleaning process using a plasma process and the like. The plasma process can be provided in an oxygen environment to remove organic contaminants in a specific embodiment. Alternatively, the surface treatment process may be a polishing process including a chemical mechanical polishing process to expose a clean surface or an active surface for further processing. Of course there can be other modifications, variations, and alternatives. As shown in FIG. 4, the method includes performing a deposition process 404 to form a polysilicon thin film material 402 overlying the surface region of the silicon substrate member. In a specific embodiment, the polysilicon thin film material may be deposited using saline (SiH₄) as a precursor. The polysilicon thin film material may also be deposited using trichlorosilane (SiHCl₃) as a precursor and hydrogen as a reducing agent. Alternatively, the polysilicon thin film material may be deposited using tetrachlorosilane (SiCl₄) as a precursor and hydrogen gas as a reducing agent. The temperature of deposition can range from about 900 Degree Celsius to about 1150 Degree Celsius depending on precursor used and other deposition parameters such as flow rates and others. Of course there can be other modifications, variations, and alternatives. For example, the polysilicon thin film material may be deposited using a physical vapor process (PVD) and others.

As shown in FIG. 5, in a specific embodiment, the polysilicon thin film material is characterized by a grain size 502 greater than about 0.05 mm, for example greater than about 0.1 mm, or greater than about 1 mm. In other embodiment, the polysilicon thin film material can have a grain size greater than about 1 cm. The polysilicon thin film material can have a thickness ranging from about 10 um to about 200 um, suitable for photovoltaic device fabrication in a specific embodiment. Of course there can be other modifications, variations, and alternatives.

In a specific embodiment, the polysilicon thin film material can be doped with suitable impurities to provide for a desirable property. In a specific embodiment, the polysilicon thin film material can be dope with a P type impurity species. Example of the P type impurity species can include boron in a preferred embodiment. In an alternative embodiment, the polysilicon thin film material may be doped with a N type impurity such as phosphorus, arsenic, antimony, and the like. These impurities can be incorporated into the polysilicon thin film material using techniques such as co-deposition, implantation, diffusion, and others. The polysilicon thin film material can have a resistivity and/or carrier mobility characteristics suitable for photovoltaic application. Of course there can be other variations, modifications, and alternatives.

Although the above has been illustrated according to a specific embodiment, there can be other modifications, alternatives, and variations. For example, the polysilicon thin film material may be doped to have other suitable impurity characteristic. The polysilicon thin film material may have various other thickness for different applications. It is therefore understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A method of forming polysilicon thin film material for photovoltaic devices, the method comprising:
providing a polycrystalline silicon substrate, the polycrystalline silicon substrate includes a surface region, a backside region, and a thickness; and
forming a polysilicon thin film material using a deposition process overlying the surface region; the polysilicon thin film material being characterized by a grain size greater than about 0.1 mm.

2. The method of claim 1 wherein the polycrystalline silicon substrate is a metallurgical grade polycrystalline silicon material.

3. The method of claim 1 wherein the polycrystalline silicon substrate is a semiconductor grade polycrystalline silicon material.

4. The method of claim 1 wherein the polycrystalline silicon substrate is a solar grade polycrystalline silicon material.

5. The method of claim 1 wherein the deposition process uses silicon precursors selected from: silane (SiH₄), trichlorosilane (SiHCl₃) and tetrachlorosilane (SiCl₄), and others.

6. The method of claim 1 wherein the polycrystalline silicon substrate is provided as a wafer.

7. The method of claim 1 wherein the polycrystalline silicon substrate is provided in a large area having a dimension greater than about 0.1 meter by 0.1 meter.

8. The method of claim 1 wherein the polysilicon thin film material is characterized by a grain size greater than about 0.05 mm.

9. The method of claim 1 wherein the polysilicon thin film material is characterized by a grain size is greater than about 1 cm.

10. The method of claim 1 wherein the polysilicon thin film material is characterized by a P type impurity characteristics.

11. A method of forming polysilicon thin film material for photovoltaic devices, the method comprising:
providing a silicon substrate member, the silicon substrate member including a surface region, a backside region, and a thickness; and
forming a polysilicon thin film material using a deposition process overlying the surface region; the polysilicon thin film material being characterized by a grain size greater than about 0.1 mm.

12. The method of claim 11 wherein the silicon substrate member is characterized by a silicon purity greater than about 99 percent (2N).

13. The method of claim 11 wherein the deposition process uses silicon precursors selected from: silane (SiH₄), trichlorosilane (SiHCl₃) and tetrachlorosilane (SiCl₄), and others.

14. The method of claim 11 wherein the silicon substrate member is provided as a wafer.

15. The method of claim 11 wherein the silicon substrate member is provided in a large area having a dimension greater than about 0.1 meter by 0.1 meter.

16. The method of claim 11 wherein the polysilicon thin film material is characterized by a grain size is greater than about 0.05 mm.

17. The method of claim 11 wherein the polysilicon thin film material is characterized by a grain size greater than about 1 cm.

18. The method of claim 11 wherein the polysilicon thin film material is characterized by a P type impurity characteristics.
